(19) United States
(12) Patent Application Publication
(10) Pub. No.: US 2025/0219043 A1
(43) Pub. Date: Jul. 3, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Ming Li, Shanghai (CN)

(73) Assignee: Yibu Semiconductor Co., Ltd., Shanghai (CN)

(21) Appl. No.: 19/004,311

(22) Filed: Dec. 28, 2024

(30) Foreign Application Priority Data
Dec. 28, 2023 (CN) 202311845466.7

(51) Int. Cl. H01L 25/00; H01L 21/48; H01L 21/56; H01L 23/00; H01L 25/07

(52) U.S. Cl. CPC H01L 25/50; H01L 21/4846; H01L 21/56; H01L 24/81; H01L 25/072; H01L 2224/81193

(57) ABSTRACT

Provided are a semiconductor packaging method, a semiconductor assembly component and an electronic device made using the method. The method comprises: forming an external connection device on one side of the carrier; attaching an interconnection device to the carrier on the same side of the carrier; electrically connecting an active surface of a first semiconductor device to the external connection device and the interconnection device; electrically connecting an active surface of a second semiconductor device to at least the interconnection device; and forming a molding layer. The semiconductor packaging method is advantageous because it does not require forming a cavity in the substrate and/or TSVs. Further, pre-molding and carrier transfer operations are not required because the molding process is carried out only once. As a result, simplification of the fabrication process for high-density interconnect packaging and reduction of associated costs are realized

### CROSS REFERENCE TO RELATED APPLICATION

The present application claims the benefit of priority under the Paris Convention to Chinese Patent Application No. 202311845466.7, filed on Dec. 28, 2023, which is incorporated herein by reference in its entirety.

### TECHNICAL FIELD

The disclosure relates to the field of semiconductor technology, and to a semiconductor packaging method, a semiconductor assembly component and an electronic device.

### BACKGROUND

With the progressive development of high-end applications, it is desirable to integrate more integrated circuit (IC) chips inside a smaller space and to make shorter interconnections between IC chips. For this reason, 2.5D/3D advanced packaging technology capable of realizing more integration and better interconnection density has received much attention. Among these advanced packaging technologies, Chip-on-Wafer-on-Substrate (CoWoS) packaging and Embedded Multi-Die Interconnect Bridge (EMIB) packaging achieve high-density electrical interconnections between chips.

However, the substrate fabrication process of the EMIB package is complicated. It requires first making a cavity in a substrate to embed a silicon bridge, and it is very difficult to control the flatness and the positioning accuracy of the silicon bridge when the silicon bridge is embedded in the substrate, as they are affected by the hardness of the substrate. The CoWoS package also requires Through Silicon Vias (TSVs), which have the drawbacks of higher technological requirements, higher cost, insufficient production capacity and the like, so it is difficult to gain broader adoption.

Therefore, there is an urgent need to develop a high-density interconnect packaging technology with simpler process and lower cost.

### SUMMARY

To solve the above technical problems, the present disclosure provides a semiconductor packaging method, a semiconductor assembly component and an electronic device.

In the first aspect, the present disclosure provides a semiconductor packaging method, comprising: forming an external connection device on one side of a carrier; providing an interconnection device and attaching the interconnection device to the carrier on the same side of the carrier where the external connection device is located; providing a first semiconductor device and electrically connecting an active surface of the first semiconductor device to the external connection device and the interconnection device; providing a second semiconductor device and electrically connecting an active surface of the second semiconductor device to at least the interconnection device; and forming a molding layer. In some embodiments, the molding layer encapsulates the external connection device, the interconnection device, the first semiconductor device and the second semiconductor device, and covers a surface on one side of the carrier facing the external connection device.

In some embodiments, the external connection device comprises a first external connector that includes first bumps.

In some embodiments, forming the external connection device on one side of the carrier comprises: forming a first seed layer on one side of the carrier; forming first bumps on one side of the first seed layer, which is away from the carrier; and removing the first seed layer.

In some embodiments, the external connection device comprises a second external connector that includes a first redistribution layer and second bumps.

In some embodiments, forming the external connection device on one side of the carrier comprises: forming a first seed layer on one side of the carrier; forming the first redistribution layer on one side of the first seed layer, which is away from the carrier; removing the first seed layer; forming a second seed layer on one side of the first redistribution layer facing away from the first seed layer; forming second bumps on one side of the second seed layer facing away from the first redistribution layer; and removing the second seed layer.

In some embodiments, the external connection device comprises a first external connector that includes first bumps, and a second external connector that includes a first redistribution layer and second bumps.

In some embodiments, forming the external connection device on one side of the carrier comprises: forming a first seed layer on one side of the carrier; forming a first redistribution layer on one side of the first seed layer facing away from the carrier; forming a second seed layer on a side of the first redistribution layer facing away from the first seed layer; forming second bumps on one side of the second seed layer facing away from the first redistribution layer; forming first bumps on one side of the first seed layer facing away from the carrier; and removing the first seed layer and the second seed layer.

In some embodiments, electrically connecting the active surface of the first semiconductor device to the external connection device and the interconnection device includes: electrically connecting the active surface of the first semiconductor device to the first external connector and the interconnection device.

In some embodiments, electrically connecting the active surface of the second semiconductor device to at least the interconnection device comprises: electrically connecting the active surface of the second semiconductor device to the second external connector and the interconnection device.

In some embodiments, the interconnection device includes a first surface, and a second surface disposed opposite to each other, the first surface including a bonding layer, the second surface including a connection pad.

In some embodiments, attaching of the interconnection device to the carrier comprises: attaching the first surface of the interconnection device to the carrier, where the second surface is flush with a surface of one side of the external connection device facing away from the carrier.

In some embodiments, the active surface of the first semiconductor device includes third bumps.

In some embodiments, electrically connecting the active surface of the first semiconductor device with the external connection device and the interconnection device includes: electrically connecting the first semiconductor device to the external connection device through some of the third bumps and to the interconnection device through the rest of the third bumps.

In some embodiments, the semiconductor packaging method further includes: removing the carrier to expose the external connection device and the interconnection device; forming a second redistribution layer on one side of the external connection device, which faces away from the first semiconductor device; and forming fourth bumps on one side of the second redistribution layer facing away from the external connection device.

In the second aspect, the present disclosure also provides a semiconductor component, which is assembled by any one of the above-mentioned semiconductor packaging methods.

In the third aspect, the present disclosure also provides an electronic equipment including the above-mentioned semiconductor component.

Compared with prior technology, the technical solution provided by present disclosure realizes the integrated packaging of the first semiconductor device and the second semiconductor device by utilizing the carrier, the external connection device, the interconnection device and the molding layer, and electrical connection of the first semiconductor device to the second semiconductor device by the interconnection device. Thus, the packaging process according to some embodiments is advantageous because it does not require forming a cavity in the substrate and/or TSVs. Further, pre-molding and carrier transfer operations are not required because the molding process is carried out only once. As a result, simplification of the fabrication process for high-density interconnect packaging and reduction of the associated costs are realized.

### BRIEF DESCRIPTION OF THE DRAWINGS

The accompanying drawings, which are incorporated in and constitute a part of this specification, illustrate embodiments consistent with the disclosure and together with the description, explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive efforts.

FIG. 1 is a schematic flowchart of a semiconductor packaging method according to an embodiment of the disclosure.

FIG. 2 is a schematic flowchart of S110 in the semiconductor packaging method shown in FIG. 1.

FIG. 3 is a schematic flowchart of S110 in the semiconductor packaging method shown in FIG. 1 according to certain embodiments.

FIG. 4 is a schematic flowchart of S110 in the semiconductor packaging method shown in FIG. 1 according to certain embodiments.

FIG. 5 is a flowchart illustrating another semiconductor packaging method according to an embodiment of the disclosure.

FIG. 6 is a flowchart of another semiconductor packaging method according to an embodiment of the disclosure.

FIG. 7 is a schematic structural diagram illustrating a semiconductor packaging method according to an embodiment of the disclosure.

FIG. 8 is a schematic structural diagram illustrating another semiconductor packaging method according to an embodiment of the disclosure.

FIG. 9 is a schematic structural diagram illustrating another semiconductor packaging method according to an embodiment of the disclosure.

FIG. 10 is a schematic structural diagram illustrating another semiconductor packaging method according to an embodiment of the disclosure.

FIG. 11 is a schematic structural diagram illustrating another semiconductor packaging method according to an embodiment of the disclosure.

FIG. 12 is a schematic structural diagram illustrating another semiconductor packaging method according to an embodiment of the disclosure.

FIG. 13 is a schematic structural diagram illustrating another semiconductor packaging method according to an embodiment of the disclosure.

### DETAILED DESCRIPTION OF THE EMBODIMENTS

In order that the above objects, features and advantages of the present disclosure may be more clearly understood, further description of aspects of the present disclosure will be provided below. It should be noted that, without conflict, the embodiments of the present disclosure and features in the embodiments may be combined with each other.

In the following description, numerous specific details are set forth to provide a thorough understanding of the present disclosure, but the present disclosure may be practiced otherwise than as described herein; it will be apparent that the embodiments in the specification are only some, but not all, embodiments of the disclosure.

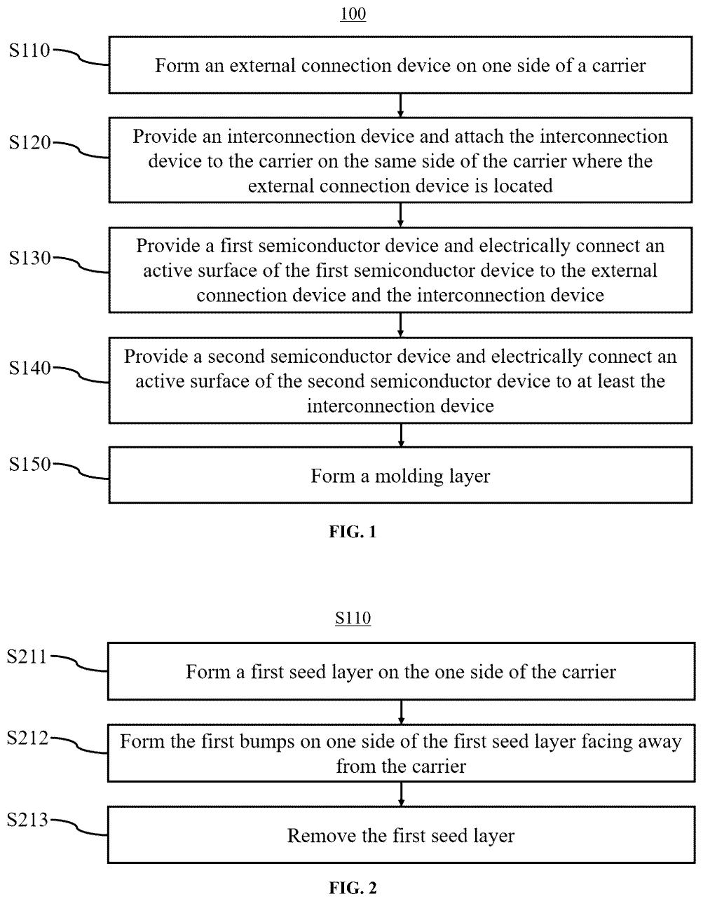

In some embodiments, as shown in FIG. 1, a semiconductor packaging method 100 using an interconnection structure includes the following steps: S110—forming an external connection device on one side of a carrier; S120—providing an interconnection device, and attaching the interconnection device to the carrier on the same side of the carrier where the external connection device is located; S130—providing a first semiconductor device, and electrically connecting an active surface of the first semiconductor device to the external connection device and the interconnection device; S140—providing a second semiconductor device and electrically connecting an active surface of the second semiconductor device to at least the interconnection device; and S150—forming a molding layer. Steps S110-S150 are described in further details below.

S110, forming an external connection device on one side of the carrier.

The embodiments of the present disclosure are not limited to the type of carrier, and any type of carrier known to those skilled in the art may be used, for example, a carrier including at least one of a glass carrier, a ceramic carrier, a metal carrier, an organic polymer material carrier, and a silicon wafer.

In this embodiment, the external connection device has conductivity, and may be made of copper, aluminum, gold, silver, or other metals known to those skilled in art, but is not limited thereto. The external connection device includes at least one of the first external connectors and the second external connectors.

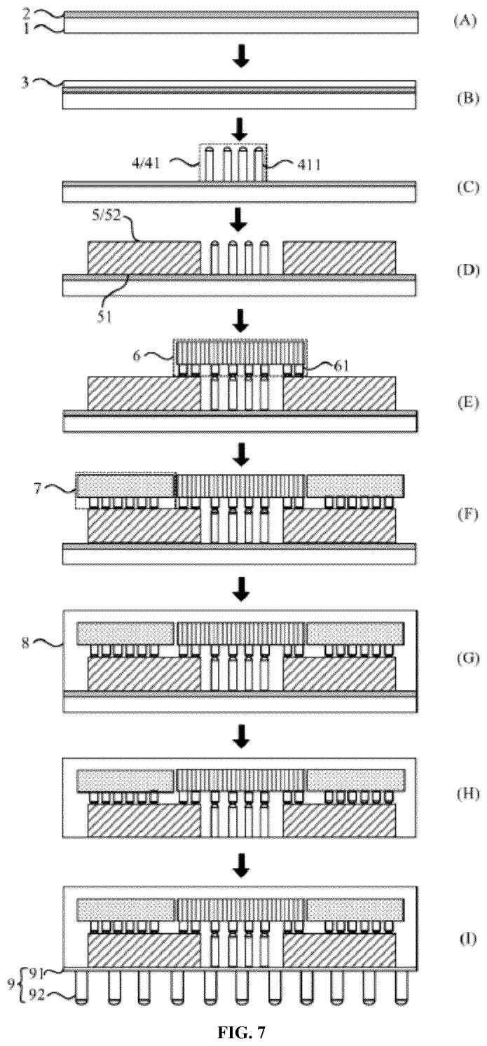

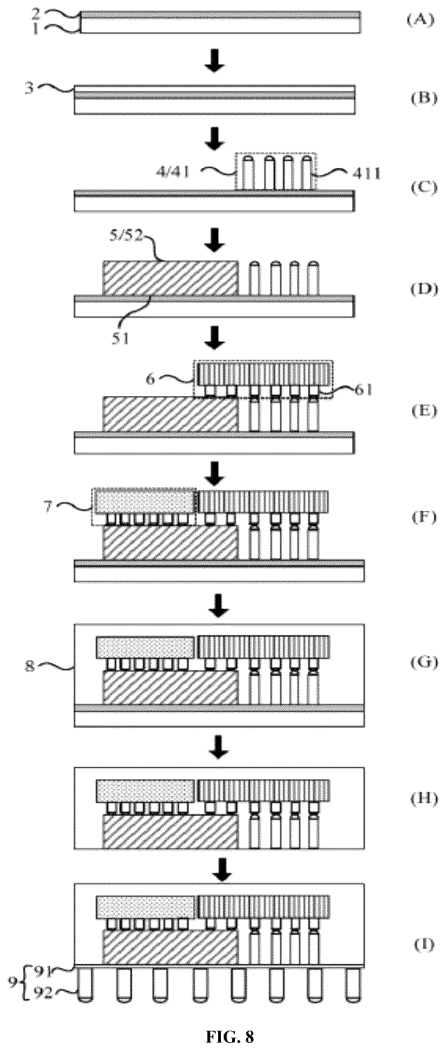

In some embodiments, as shown in step (C) of any one of FIGS. 7-9, the external connection device 4 includes a first external connector 41, the first external connector 41 includes first bumps 411, and a solder is disposed on top of each of the first bumps 411.

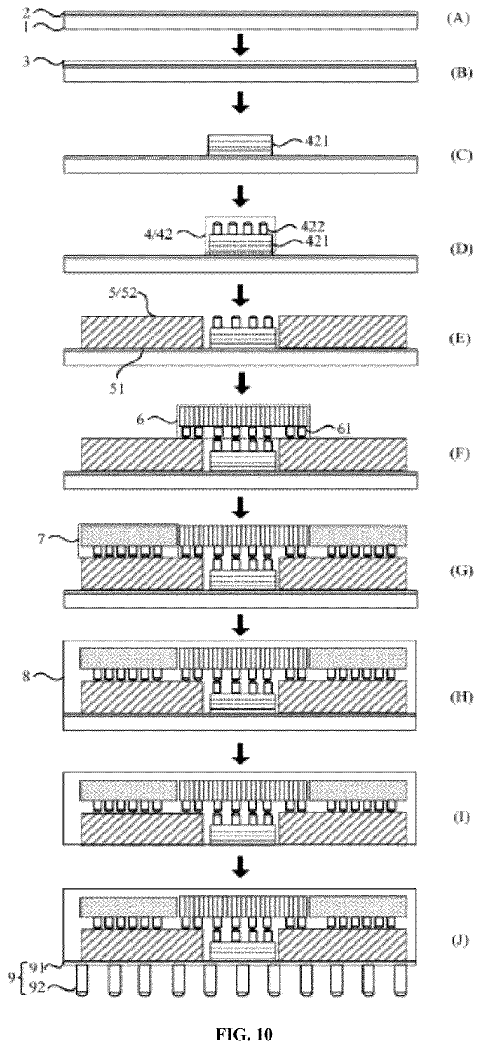

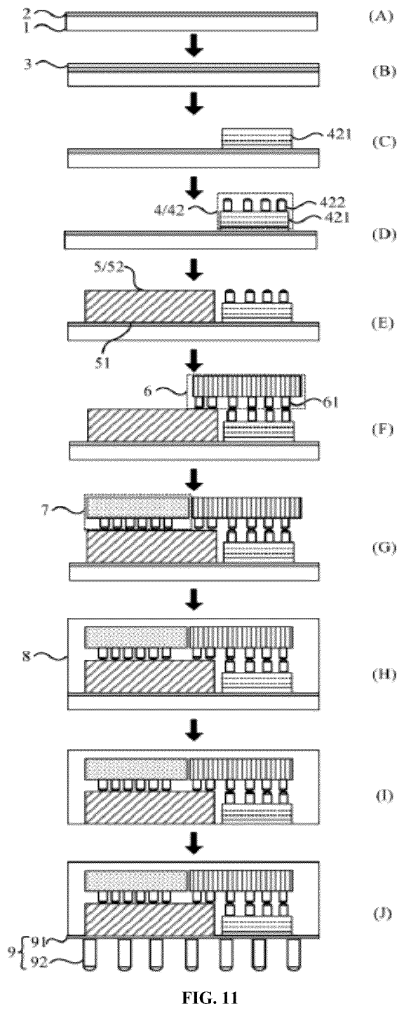

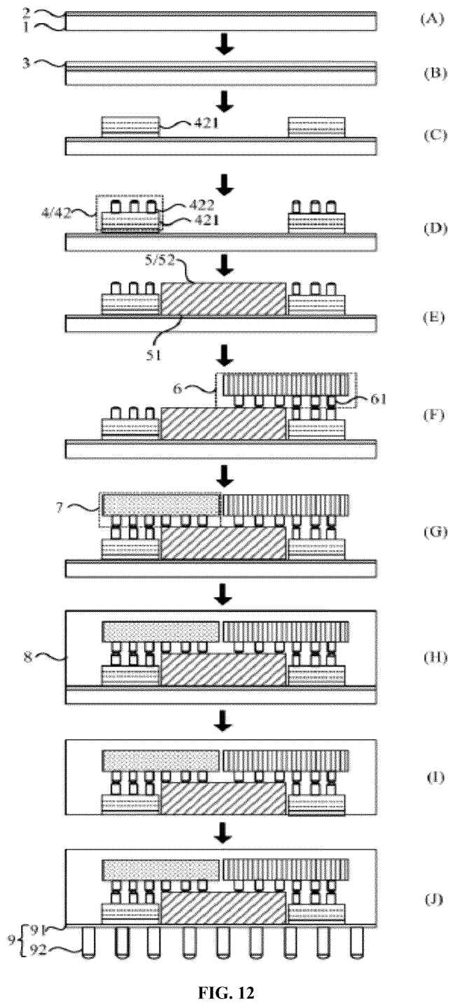

In some embodiments, as shown in steps (C) to (D) of any of FIGS. 10-12, the external connection device 4 includes a second external connector 42, the second external connector 42 including a first redistribution layer 421 and second bumps 422. The first redistribution layer 421 includes at least one patterned metal layer and at least one insulating layer, and each of the second bumps 422 is a micro bump (uBump) with a solder disposed on top.

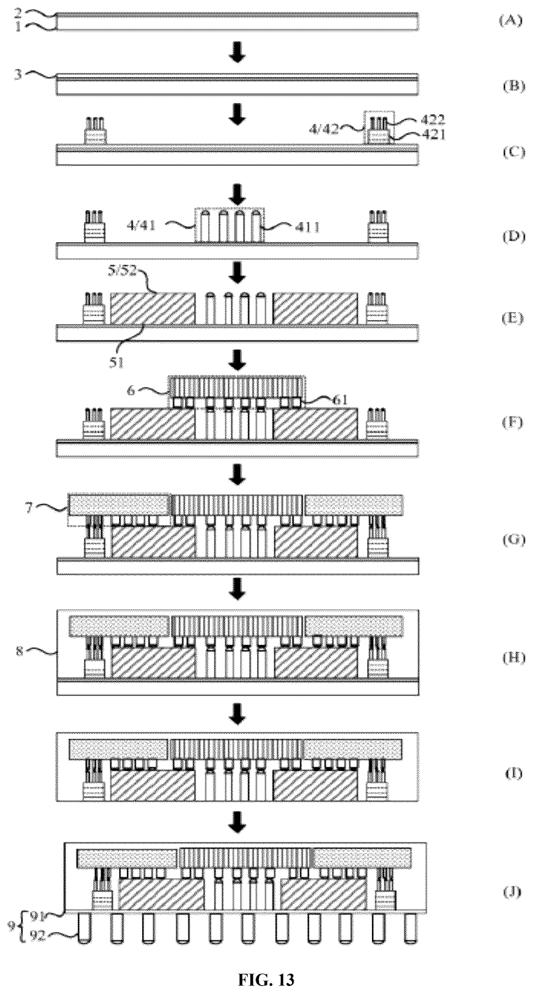

In some embodiments, as shown in steps (C) to (D) of FIG. 13, the external connection device 4 includes a first external connector 41 and a second external connector 42.

S120, providing an interconnection device, and attaching the interconnection device to the carrier on the same side of the carrier where the external connection device is located.

In this embodiment, the interconnection device may comprise a silicon bridge, including any device having the local interconnect function known to those skilled in technology, which is not limited herein.

Referring to FIGS. 7-13, the interconnection device 5 comprises a first surface 51 and a second surface 52, the second surface 52 being provided with connection pads, the first surface 51 of the interconnection device 5 being directed towards the carrier 1, the interconnection device 5 being secured to the carrier 1 by means of a bonding layer. The interconnection device 5 is located on the same side of the carrier 1 where the external connection device 4 is located. The bonding layer includes Die Attach Film (DAF), but is not limited thereto, and includes other materials having an adhesive function known to those skilled in technology.

In this embodiment, the external connection device 4 is formed first on one side of the carrier 1, and then the first surface 51 of the interconnection device 5 is attached to carrier 1, with the second surface 52 provided with connection pads facing away from the carrier 1. On the one hand, the dielectric layer is absent, so there is no need to open holes in the dielectric layer, which simplifies the manufacturing process of the external connection device 4 and helps reduce costs; on the other hand, there is no need to provide a substrate with a cavity for embedding the interconnection device 5, and the connection pads of the interconnection device 5 are facing away from the carrier 1, also there is no need to perform pre-molding and carrier transfer operations, no need to open holes in the interconnection device 5, the subsequent steps can be performed to electrically connect the first semiconductor device 6 to the interconnection device 5, further simplifying the packaging process.

S130, providing a first semiconductor device, and electrically connecting the active surface of the first semiconductor device to the external connection device and the interconnection device.

In this embodiment, the first semiconductor device includes, but is not limited to, a Die, a Chip, a High Bandwidth Memory (HBM), a System-on-a-Chip (SOC), an Application Specific Integrated Circuit (ASIC), and a Programmable Logic Device (PLD).

As described in connection with step (E) of any of FIGS. 7-9 (or step (F) of any of FIGS. 10-13), the first semiconductor device 6 includes oppositely disposed passive surface and active surface, the active surface being provided with a plurality of third bumps 61. In this step, the active surface of the first semiconductor device 6 is directed to the external connection device 4, some of the third bumps 61 are electrically connected to the external connection device 4, and the rest of the third bumps 61 are electrically connected to the connection pads of the interconnection device 5.

S140, providing a second semiconductor device 7 and electrically connecting the active surface of the second semiconductor device 7 to at least the interconnection device 5.

In this embodiment, the second semiconductor device includes, but is not limited to, a Die, a Chip, a High Bandwidth Memory (HBM), a System-on-a-Chip (SOC), an Application Specific Integrated Circuit (ASIC), and a Programmable Logic Device (PLD).

As shown in step (F) of any of FIGS. 7 to 9 (or step (G) of any of FIGS. 10 to 13), the second semiconductor device 7 includes a passive surface and an active surface disposed opposite to each other, the active surface being provided with a plurality of connection bumps. In this step, the active surface of the second semiconductor device 7 is directed towards the interconnection device 5, and the connection bumps are electrically connected to at least the connection pads of the interconnection device 5. In this way, the first semiconductor device 6 and the second semiconductor device 7 are electrically connected to each other through the interconnection device 5.

In some embodiments, as shown in FIGS. 7-8 and FIGS. 10-11, the connection bumps of the second semiconductor device 7 are electrically connected to only the connection pads of the interconnection device 5. In this way, the first semiconductor device 6 and the second semiconductor device 7 are electrically connected to each other through the interconnection device 5, and the second semiconductor device 7 can be electrically connected to an external device through the interconnection device 5, the first semiconductor device 6, and the external connection device 4.

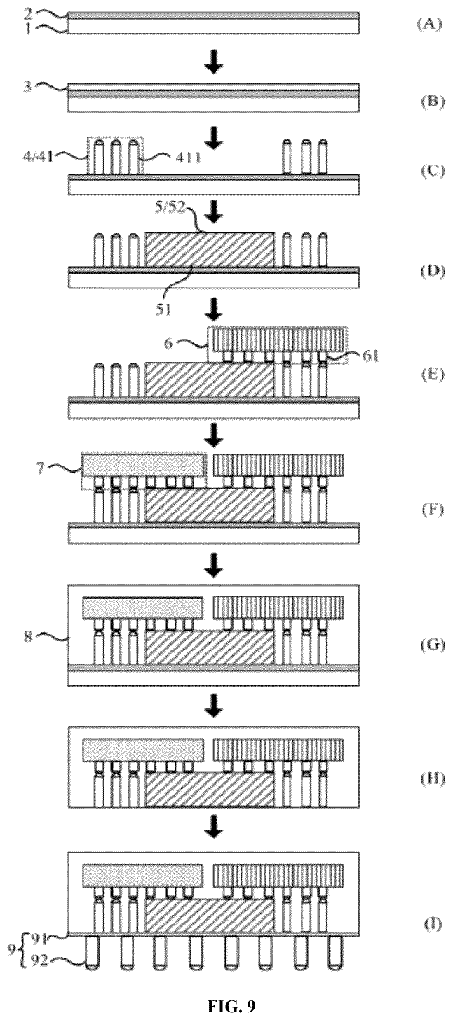

In some embodiments, as shown in FIGS. 9, 12 and 13, some of the connection bumps of the second semiconductor device 7 are electrically connected to the connection pads of the interconnection device 5, and the rest of the connection bumps are electrically connected to the external connection device 4. In this way, the first semiconductor device 6 and the second semiconductor device 7 are electrically connected to each other through the interconnection device 5, and the second semiconductor device 7 is electrically connected to an external device through the external connection device 4.

S150, forming a molding layer 8.

In this embodiment, in combination with step (G) of any of FIGS. 7 to 9 (or step (H) of any of FIGS. 10 to 13), the molding process such as transfer molding, compression molding or printing may be used for the molding, and the material for preparing the molding layer 8 includes a molding compound of a molding material (e.g., epoxy resin). The molding layer 8 and the first semiconductor device 6 are located on the same side of the carrier 1, and the molding layer 8 not only encapsulates the external connection device 4, the interconnection device 5, the first semiconductor device 6 and the second semiconductor device 7, but also fills in the gaps among the external connection device 4, the interconnection device 5, the first semiconductor device 6 and the second semiconductor device 7, and also covers the unoccupied surface of the side of the carrier 1 facing the external connection device 4.

In this embodiment, the connection pads of the interconnection device 5 are away from the carrier 1, and subsequent steps can be performed without pre-molding and carrier transfer operations. This semiconductor packaging method only requires one molding process, which simplifies the packaging process and helps reduce costs.

It should be noted that, in the embodiments of the present disclosure, the numbers of the first semiconductor device 6 and the second semiconductor device 7 are not limited. FIGS. 7 to 13 only show that the number of the first semiconductor device 6 is one, the number of the second semiconductor device 7 is one or two, and the numbers of the first semiconductor device 6 and the second semiconductor device 7 can be flexibly set according to the requirement.

The semiconductor packaging method provided by the embodiments of the disclosure comprises the following steps: forming an external connection device 4 on one side of the carrier 1; providing an interconnection device 5 and attaching the interconnection device 5 to the carrier 1 on the same side of the carrier 1 where the external connection device 4 is located; providing a first semiconductor device 6 and electrically connecting the active surface of the first semiconductor device 6 to the external connection device 4 and the interconnection device 5; providing a second semiconductor device 7 and electrically connecting the active surface of the second semiconductor device 7 to at least the interconnection device 5; and forming a molding layer 8, where the molding layer 8 encapsulates the external connection device 4, the interconnection device 5, the first semiconductor device 6 and the second semiconductor device 7, and covers a side surface of the carrier 1 facing the external connection device 4. Therefore, the semiconductor packaging method realizes the integrated packaging of the first semiconductor device 6 and the second semiconductor device 7 by the carrier 1, the external connection device 4, the interconnection device 5 and the molding layer 8, electrical connection of the first semiconductor device 6 to the second semiconductor device 7 by the interconnection device, and electrical connection of the first semiconductor device 6 and the second semiconductor device 7 to an external device through the external connection device 4. Thus, the packaging process in the embodiments of the disclosure does not require forming a cavity in the substrate and/or TSVs. Further, pre-molding and carrier transfer operations are not required because the molding process is carried out only once. As a result, simplification of the fabrication process and reduction of the costs are realized

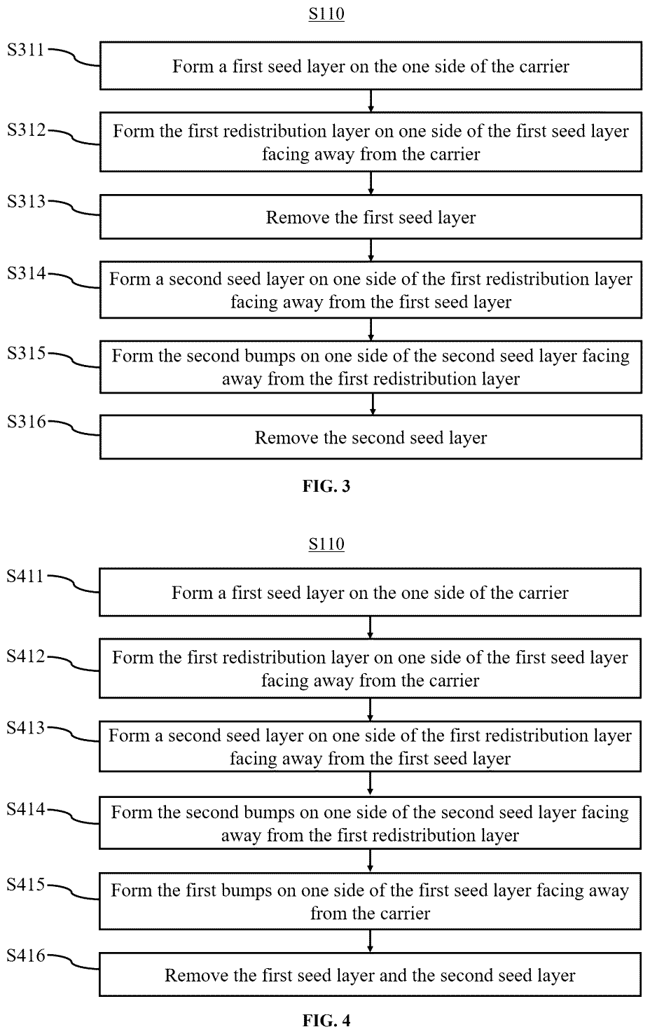

In some embodiments, as shown in FIG. 7, the external connection device 4 includes a first external connector 41, the first external connector includes first bumps 411. As shown in FIG. 2, S110-forming the external connection device 4 on one side of the carrier includes steps S211 to S213 described below.

S211, forming a first seed layer 3 on one side of carrier 1.

In connection with steps (A)-(B) of any of FIGS. 7-9, a release tape layer 2 is formed on one side of the carrier 1, and then a first seed layer 3 is formed on a side of the release tape layer 2 facing away from the carrier 1. The first seed layer 3 comprises at least one of copper and titanium.

S212, forming a first bump 41 on one side of the first seed layer 3 facing away from carrier 1.

In connection with step (C) of any of FIGS. 7-9, a photoresist layer is coated on a side of the first seed layer 3 facing away from the release tape layer 2, and after exposure and development, via holes are formed through the photoresist layer, first bumps 411 are formed in the via holes by an electroplating process, and the photoresist layer is removed. The photoresist layer may be a positive photoresist or a negative photoresist, which is not limited herein.

S213, removing the first seed layer 3.

In step (C) in connection with any of FIGS. 7 to 9, after removing the photoresist, the first seed layer 3 except the area occupied by the first bumps 411 is removed by an etching process.

In this embodiment, the external connection device 4 has a first external connector 41, the first external connector 41 includes first bumps 411, and solder is disposed on a side of each of the first bumps 411 facing away from the carrier 1.

In some embodiments, as shown in FIG. 10, the external connection device 4 includes a second external connector 42, which has a first redistribution layer 421 and second bumps 422. As shown in FIG. 3, S110—forming the external connection device 4 on one side of the carrier 1 includes steps S311 to S316 described below.

S311, forming a first seed layer 3 on one side of the carrier 1.

In connection with steps (A)-(B) of any of FIGS. 10-12, a release tape layer 2 is formed on one side of the carrier 1, and then a first seed layer 3 is formed on a side of the release tape layer 2 facing away from the carrier 1. The first seed layer 3 comprises at least one of copper and titanium.

S312, forming a first redistribution layer 421 on one side of the first seed layer 3 facing away from the carrier 1.

In this embodiment, the first redistribution layer 421 includes at least one patterned metal layer and at least one insulating layer. The metal layer is made of a metal material with good conductivity, including but not limited to copper, titanium, gold, silver, aluminum and tin. S313, removing the first seed layer 3.

In this step, as shown in step (C) of any one of FIGS. 10 to 12, the first seed layer 3 except the area occupied by the first redistribution layer 421 is removed by an etching process, i.e., the first seed layer 3 under the first redistribution layer 421 remains.

S314, forming a second seed layer on one side of the first redistribution layer 421 facing away from the first seed layer.

In this step, the method for fabricating the second seed layer (not shown) is the same as the method for fabricating the first seed layer 3 and will not be described here again.

S315, forming second bumps 422 on one side of the second seed layer facing away from the first redistribution layer.

In connection with step (D) of any of FIGS. 10-12, the second bumps 422 are formed on a side of the second seed layer facing away from the first redistribution layer 421 using an electroplating or deposition process. The second bumps 422 are prepared by a method like that of the first bumps 411 and will not be described herein.

S316, removing the second seed layer.

In this step, the second seed layer is removed except the area occupied by the second bumps 422 by an etching process, i.e., the second seed layer under the second bumps 422 remains.

In this embodiment, the external connection device 4 has a second external connector 42, where the second external connector 42 includes a first redistribution layer 421 and second bumps 422, and a solder is disposed on each of the second bumps 422 facing away from the first redistribution layer 421.

In some embodiments, as shown in FIG. 13, the external connection devices 4 include at least one first external connector 41 and at least one second external connector 42, the first external connector 41 including first bumps 411, the second external connector 42 including a first redistribution layer 421 and second bumps 422. As shown in FIG. 4, S110—forming the external connection device 42 on the carrier 1 includes steps S411 to S416 described below.

S411, forming a first seed layer on one side of the carrier.

In connection with steps (A)-(B) of FIG. 13, a release tape layer 2 is formed on one side of the carrier 1, and then a first seed layer 3 is formed on a side of the release tape layer 2 facing away from the carrier 1. The first seed layer 3 comprises at least one of copper and titanium.

S412, forming a first redistribution layer on one side of the first seed layer facing away from carrier 1.

The step is the same as S312, and the explanation of S312 is not repeated here.

S413, forming a second seed layer on one side of the first redistribution layer 421 facing away from the first seed layer 3.

In this step, the method for fabricating the second seed layer (not shown) is the same as the method for fabricating the first seed layer 3 and will not be described here again.

S414, forming second bumps 422 on one side of the second seed layer facing away from the first redistribution layer 421.

The step is the same as S315, and the explanation of S315 is not repeated here.

S415, forming first bumps 411 on one side of the first seed layer 3 facing away from carrier 1.

The step is the same as S212, and the explanation of S212 is specifically referred to, and will not be repeated here.

And S416, removing the first seed layer 3 and the second seed layer.

In this step, the first seed layer 3 except the area occupied by the first bumps 411 and the first redistribution layer 421 and a part of the second seed layer on the upper surface of the first redistribution layer 421 which is not occupied by the second bumps 422 are removed by an etching process.

In this embodiment, the external connection device 4 includes the first external connector 41 and the second external connector 42, the first external connector 41 includes the first bumps 411, and the second external connector 42 includes the first redistribution layer 421 and the second bumps 422. A height of a surface on one side of the first external connector 41 facing away from the carrier 1 is equal to a height of a surface on one side of the second external connector 42 facing away from the carrier 1, the first bump 411 and the second bump 422 have different heights, and a height of the first bump 411 is greater than a height of the second bump 422. The diameter of the first bump 411 and the diameter of the second bump 422 may be the same or different. Note that the present embodiment only exemplarily shows that the second external connector 42 is prepared first and then the first external connector 41 is prepared, but does not constitute a limitation of the semiconductor packaging method provided by the embodiments of the present disclosure. In other embodiments, the first external connector 41 may be prepared first, and the second external connector 42 may be prepared later, which is not limited herein.

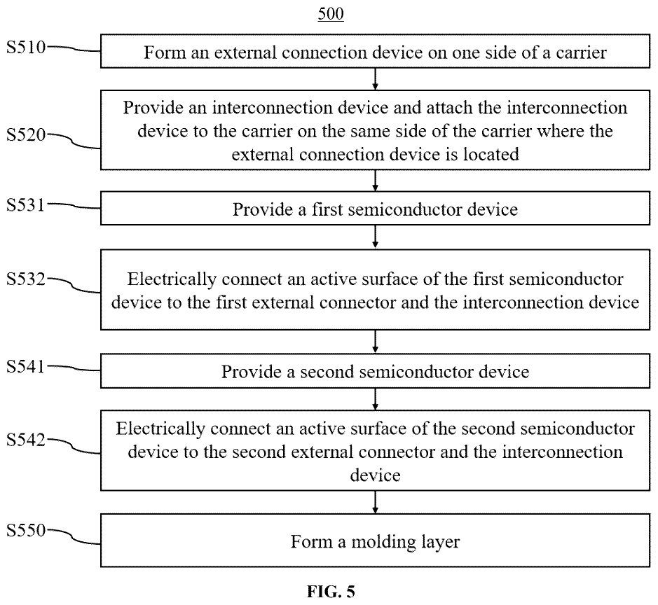

FIG. 5 is a flowchart illustrating another semiconductor packaging method 500 including steps S510, S520, S531, S532, S541, S542, and S550, according to an embodiment of the disclosure.

In this embodiment, S510 to S520 are the similar to S110 to S120, and are not described here again.

S532, electrically connecting an active surface of the first semiconductor device 6 to the first external connector 41 and the interconnection device 5.

As shown in step (F) of FIG. 13, the active surface of the first semiconductor device 6 is directed toward the first external connector 41 and the interconnection device 5, and the first semiconductor device 6 is electrically connected to the first external connector 41 and the interconnection device 5, i.e., the first semiconductor device 6 is connected across the first external connector 41 and the interconnection device 5.

The “electrically connecting the active surface of the second semiconductor device 7 to at least the interconnection device 5” includes step S542 described below.

S542, electrically connecting the active surface of the second semiconductor device 7 to the second external connector 42 and the interconnection device 5.

As shown in step (G) of FIG. 13, the active surface of the second semiconductor device 7 is directed toward the second external connector 42 and the interconnection device 5, and the second semiconductor device 7 is electrically connected to the second external connector 42 and the interconnection device 5, i.e., the second semiconductor device 7 is connected across the second external connector 42 and the interconnection device 5.

It should be noted that FIG. 13 only exemplarily illustrates that the first semiconductor device 6 is connected across the first external connector 41 and the interconnection device 5, and the second semiconductor device 7 is connected across the second external connector 42 and the interconnection device 5, but does not limit the semiconductor packaging method provided by the embodiment of the present disclosure. In other embodiments, the first semiconductor device 6 may also be connected across the second external connector 42 and the interconnection device 5, and the second semiconductor device 7 may be connected across the first external connector 41 and the interconnection device 5, which is not limited herein.

In some embodiments, the interconnection device 5 comprises oppositely disposed first and second surfaces 51 and 52, the first surface 51 comprising a bonding layer and the second surface 52 comprising connection pads, the “attaching interconnection device to carrier” includes: attaching the first surface 51 of the interconnection device 5 to the carrier 1, with the second surface 52 flush with a surface on one side of the external connector facing away from the carrier 1.

In this embodiment, the bonding layer includes DAF tape, and other materials with adhesive function known to those skilled in technology but is not limited thereto.

The height of the second surface 52 of the interconnection device 5 refers to the distance of the second surface 52 from the surface on one side of the carrier 1 facing the interconnection device 5. The interconnection device 5 comprises a silicon bridge, a redistribution layer on a side of the silicon bridge facing away from the carrier 1 and a connection pad on a side of the redistribution layer facing away from the silicon bridge. In some embodiments, the redistribution layer comprises at least one patterned metal layer and at least one insulating layer, and the insulating layer is made from Polyimide (PI). Illustratively, the redistribution layer comprises 3 patterned metal layers and 3 insulating layers.

In some embodiments, as shown in any of FIGS. 7-9, the second surface 52 of the interconnection device 5 is flush with a surface of a side of the external connection device 4 (i.e., the first external connector 41) facing away from carrier 1.

In some embodiments, as shown in any of FIGS. 10-12, the second surface 52 of the interconnection device 5 is flush with a surface of a side of the external connection device 4 (i.e., the second external connector 42) facing away from the carrier. The height of the second surface 52 is equal to the sum of a thickness of the DAF tape, a thickness of a body (including the silicon bridge, and the redistribution layer on the side of the silicon bridge facing away from the carrier 1) of the interconnection device 5, and a thickness of the connection pad, and the height of the second external connector 42 is equal to the sum of a height of the first redistribution layer 421, a height of the second bump 422, and a height of the solder paste. For example, in the case where the thickness of the DAF tape is 10 μm, the thickness of the body of the interconnection device 5 is 80 μm and the thickness of each of the connection pads is 15 μm, the height of the second surface 52 is105 μm; and in the case where the height of the first redistribution layer 421 is 25 μm, the height of each of the second bumps 422 is 50 μm and the height of the solder paste on the top of each of the second bump 422 is 30 μm, the overall height of the second external connector 42 is 105 μm, i.e., the surface on one side of the second external connector 42 facing away from the carrier 1 is flush with the second surface 52 of the interconnection device 5.

In some embodiments, as shown in FIG. 13, the second surface 52 of the interconnection device 5 is flush with the surface on one side of the external connection device 4 (i.e., the first external connector 41 and the second external connector 42) facing away from carrier 1.

In some embodiments, the active surface of the first semiconductor device 6 includes third bumps, and the “electrically connecting the active surface of the first semiconductor device 7 to the external connection device 4 and the interconnection device 5” includes: electrically connecting the first semiconductor device 6 to the external connection device 4 through some of the third bumps, and is electrically connected to the interconnection device 5 through the rest of the third bumps.

In this embodiment, as shown in any one of FIGS. 7 to 13, the active surface of the first semiconductor device 6 is provided with third bumps 61, and a solder is disposed on a side of each of the third bumps 61 facing away from the first semiconductor device 6. The first semiconductor device 6 is electrically connected to the external connection device 4 and the interconnection device 5 through the third bumps 61, and each of the top of the first bump 411 of the first external connector 41 and the top of the second bump 422 of the second external connector 42 is provided with a solder. The solder is a bump, has a certain hardness, is not easy to collapse in the welding process, and a bump pitch and a bump diameter can be configured for a higher density. For example, the minimum bump pitch is 73 μm, and the bump diameter is 28 μm.

In this embodiment, a height of a surface on one side of the first external connector 41 facing away from the carrier 1 is equal the carrier 1 is equal to a height of a surface on one side of the second external connector 42 facing away from is equal, heights of the first bump 411 and the second bump 422 are different, and a height of the first bump 411 is greater than a height of the second bump 422. The diameter of the first bump 411 and the diameter of the second bump 422 may be the same or different. The diameters of the first bump 411 and the second bump 422 are larger than the diameter of the third bump 61. For example, the diameter of the first bump 411 is 70 μm, and the diameter of the third bump 61 is 28 μm. In some embodiments, all the third bumps 61 are set to have the same diameter, which is advantageous for simplifying the fabrication process.

In some embodiments, the solder on the top of a respective third bump 61 of the third bumps 61 is aligned with the solder on the top of a respective bump 411 of the first bumps 411. The respective third bump 61 is connected to the respective first bump 411 and a respective third bump 61 is connected to a respective connection pad of the interconnection device 5 by rapid heating the solders using a Thermal Compression Bond (TCB) process.

In some embodiments, the active surface of the second semiconductor device 7 is provided with fifth bumps, which may have the same height and diameter as the third bumps 61, or may be different from the third bumps 61 in height and diameter, which is not limited herein.

It should be noted that the third bumps 6 and the fifth bumps are bump structures formed on the original connection pads of the corresponding semiconductor devices, and may have different heights and diameters, but the connection pads of the first semiconductor device 6 and the second semiconductor device 7 for connection to the interconnection device 5 are the same.

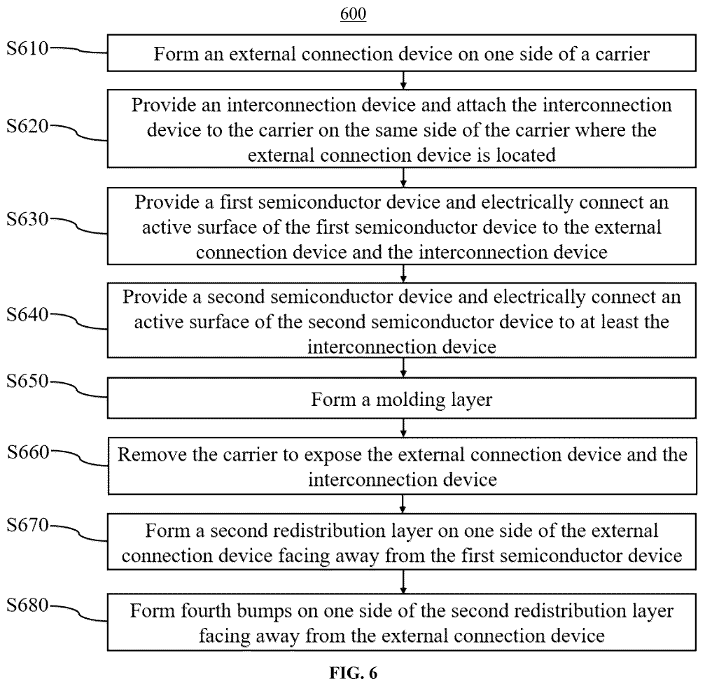

FIG. 6 is a flowchart illustrating another semiconductor packaging method 600 including steps S610, S620, S630, S640 S650, S660, and S670, according to an embodiment of the present disclosure.

In this embodiment, S610 through S650 are the similar to S110 to S150, and are not described here again.

In some embodiments, as shown in FIG. 6, after the “forming the molding layer 8”, the semiconductor packaging method 600 using the interconnection structure further includes steps S660 to S680 described below.

S660, removing the carrier 1 to expose the external connection device 4 and the interconnection device 5.

After the molding layer 8 is cured, the carrier 1 and the release tape layer 2 are removed as shown in step (H) of any one of FIGS. 7 to 9 (or as shown in step (I) of any one of FIGS. 10 to 13). The carrier 1 is removed in a suitable manner depending on the type of the release tape layer 2. For example, when the release tape layer 2 is pyrolytic, the carrier 1 and the release tape layer 2 are removed by heating; and when the release tape layer 2 is light-irradiated, the carrier 1 and the release tape layer 2 are removed by adopting a UV irradiation mode. The carrier 1 and the release tape layer 2 may also be removed by chemical etching.

S670, forming a second redistribution layer on one side of the external connection device 4, which faces away from the first semiconductor device 6.

S680, forming fourth bumps 92 on one side of the second redistribution layer 91 facing away from the external connection device 4.

As shown in step (I) of any of FIGS. 7 to 9 (or step (J) of any of FIGS. 10 to 13), the molding layer 8 is formed with a second redistribution layer 91 on a side facing away from the first semiconductor device 6, the second redistribution layer 91 is electrically connected to the external connection device 4, and then fourth bumps 92 are formed on a side of the second redistribution layer 91 facing away from the external connection device 4, and the fourth bumps 92 are electrically connected to the second redistribution layer 91. The first semiconductor device 6 and the second semiconductor device 7 may be electrically connected to an external device through the external connection device 4, the second redistribution layer 91, and the fourth bumps 92.

It should be noted that the embodiments of the present disclosure does not limit the shape of the fourth bumps 92, and FIGS. 7-13 only exemplarily illustrate that the shape of the fourth bumps 92 is a pillar shape. In other embodiments, the fourth bumps 92 may be configured to have other shapes known to those skilled in technology, such as a sphere shape. The external device includes, but is not limited to, a substrate, a printed circuit board (PCB), or other types of electronic devices known to those skilled in technology, which is not limited herein.

On the basis of the foregoing embodiments, the embodiments of the present disclosure further provide a semiconductor assembly, where the semiconductor assembly is packaged by any one of the foregoing semiconductor packaging methods, and has corresponding beneficial effects, and to avoid repetitive description, no further description is given here.

In some embodiments, as shown in any of FIGS. 7-13, the semiconductor assembly includes: an external connection device 4, an interconnection device 5, a first semiconductor device 6, a second semiconductor device 7, and a molding layer 8. In this embodiment, the active surface of the first semiconductor device 6 is electrically connected to the external connection device 4 and the interconnection device 5, the active surface of the second semiconductor device 7 is electrically connected to at least the interconnection device 5, the first semiconductor device 6 and the second semiconductor device 7 are positioned on the same side of the interconnection device 5, and the molding layer 8 encapsulates the external connection device 4, the interconnection device 5, the first semiconductor device 6 and the second semiconductor device 7.

In some embodiments, as shown in any of FIGS. 7-9, in the semiconductor assembly, the external connection device 4 includes a first external connector 41, the first external connector 41 including first bumps 411.

In some embodiments, as shown in any of FIGS. 10-12, in the semiconductor assembly, the external connection device 4 includes a second external connector 42, the second external connector 42 including a first redistribution layer 421 and second bumps 422.

In some embodiments, as shown in FIG. 13, in the semiconductor assembly, the external connection device 4 includes a first external connector 41 and a second external connector 42, the first external connector 41 includes first bumps 411, and the second external connector 42 includes a first redistribution layer 421 and second bumps 422.

In some embodiments, as shown in FIG. 13, in the semiconductor assembly, the active surface of the first semiconductor device 6 is electrically connected to the first external connector 41 and the interconnection device 5, and the active surface of the second semiconductor device 7 is electrically connected to the second external connector 42 and the interconnection device 5.

In some embodiments, as shown in any of FIGS. 7-13, in the semiconductor assembly, the interconnection device 5 includes a first surface 51 and a second surface 52 disposed opposite to each other, the first surface 51 includes a bonding layer, the second surface 52 includes a connection pad, and the height of the interconnection device 5 is equal to the height of the external connector 4, i.e., the second surface 52 is flush with a plane in which the connection end of the external connector 4 is located.

In some embodiments, as shown in any of FIGS. 7-13, in the semiconductor assembly, the first semiconductor device 6 includes third bumps 61, the third bumps 61 being located on a side of the first semiconductor device 6 facing the external connector 4, some of the third bumps 61 being electrically connected to the external connection device 4, and the rest of third bumps 61 being electrically connected to the interconnection device 5.

In some embodiments, as shown in any of FIGS. 7-13, the semiconductor assembly further comprises: a second redistribution layer 91 and fourth bumps 92; the second redistribution layer 91 is located on a side of the external connection device 4 facing away from the first semiconductor device 6 and is electrically connected to the external connection device 4; and the fourth bumps 92 are located on a side of the second redistribution layer 91 facing away from the external connection device 4 and are electrically connected to the second redistribution layer 91.

On the basis of the foregoing implementation manner, the embodiments of the present disclosure further provide an electronic device, which includes the semiconductor component and has corresponding beneficial effects, and to avoid repeated description, the description is not presented herein.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” “include,” or any other variation thereof, are intended to cover a non-exclusive inclusion, such that a process, method, material, or equipment that comprises a list of elements does not include only those elements but may include other elements not expressly listed or inherent to such process, method, material, or equipment. Without further limitation, an element defined by the phrase “comprising one . . . ” does not exclude the presence of other like elements in a process, method, material, or equipment that comprises the element.

The foregoing are merely specific embodiments of the disclosure to enable one skilled in technology to understand or practice the disclosure. Various modifications to these embodiments will be readily apparent to those skilled in technology, and the generic principles defined herein may be applied to other embodiments without departing from the spirit or scope of the disclosure. Thus, the present disclosure is not intended to be limited to the embodiments shown and described herein but is to be accorded with the widest scope consistent with the principles and novel features disclosed herein.

What is claimed is:

1. A semiconductor packaging method, comprising:
forming an external connection device on one side of a carrier;
providing an interconnection device and attaching the interconnection device to the carrier on the same side of the carrier where the external connection device is formed;
providing a first semiconductor device and electrically connecting an active surface of the first semiconductor device to the external connection device and the interconnection device;
providing a second semiconductor device and electrically connecting an active surface of the second semiconductor device to at least the interconnection device; and
forming a molding layer, wherein the molding layer encapsulates the external connection device, the interconnection device, the first semiconductor device and the second semiconductor device, and covers a surface on the one side of the carrier.

2. The semiconductor packaging method of claim 1, wherein the external connection device includes a first external connector that includes first bumps; and wherein forming the external connection device on the one side of the carrier includes:
forming a first seed layer on the one side of the carrier;
forming the first bumps on one side of the first seed layer facing away from the carrier; and
removing portions of the first seed layer not covered by the first bumps.

3. The semiconductor packaging method of claim 1, wherein the external connection device includes a second external connector that includes a first redistribution layer and second bumps; and wherein forming the external connection device on the one side of the carrier includes:
forming a first seed layer on the one side of the carrier;
forming the first redistribution layer on one side of the first seed layer facing away from the carrier;
removing portions of the first seed layer not covered by the first redistribution layer;
forming a second seed layer on one side of the first redistribution layer facing away from the first seed layer;
forming the second bumps on one side of the second seed layer facing away from the first redistribution layer; and
removing portions of the second seed layer not covered by the second bumps.

4. The semiconductor packaging method of claim 1, wherein the external connection device includes a first external connector and a second external connector, the first external connector includes first bumps, and the second external connector includes a first redistribution layer and second bumps; and wherein forming the external connection device on the one side of the carrier includes:
forming a first seed layer on the one side of the carrier;
forming a first redistribution layer on one side of the first seed layer facing away from the carrier;
forming a second seed layer on one side of the first redistribution layer facing away from the first seed layer;
forming the second bumps on one side of the second seed layer facing away from the first redistribution layer;
forming the first bumps on one side of the first seed layer facing away from the carrier; and
removing portions of the first seed layer and portions of the second seed layer, wherein the portions of the first seed layer are not covered by the first redistribution layer or the first bumps and the portions of the second seed layer are not covered by the second bumps.

5. The semiconductor packaging method of claim 4, wherein electrically connecting the active surface of the first semiconductor device to the external connection device and the interconnection device includes: electrically connecting the active surface of the first semiconductor device to the first external connector and the interconnection device; and
wherein electrically connecting the active surface of the second semiconductor device to at least the interconnection device includes: electrically connecting the active surface of the second semiconductor device to the second external connector and the interconnection device.

6. The semiconductor packaging method of claim 1, wherein the interconnection device includes a first surface and a second surface that are opposite to each other, the first surface includes an adhesive layer, and the second surface includes a connection pad; and wherein attaching the interconnection device to the carrier includes:
attaching the first surface of the interconnection device to the carrier, wherein the second surface is flush with a surface on one side of the external connection device facing away from the carrier.

7. The semiconductor packaging method according to claim 1, wherein the active surface of the first semiconductor device includes third bumps; and wherein electrically connecting the active surface of the first semiconductor device to the external connection device and the interconnection device includes:
electrically connecting the first semiconductor device to the external connection device through some of the third bumps and to the interconnection device through the rest of the third bumps.

8. The semiconductor packaging method according to claim 1, further comprising:
removing the carrier to expose the external connection device and the interconnection device;
forming a second redistribution layer on one side of the external connection device facing away from the first semiconductor device; and
forming fourth bumps on one side of the second redistribution layer facing away from the external connection device.

9. The semiconductor packaging method of claim 2, wherein the interconnection device includes a first surface and a second surface that are opposite to each other, the first surface includes an adhesive layer, and the second surface includes a connection pad; and wherein attaching the interconnection device to the carrier includes:
attaching the first surface of the interconnection device to the carrier, wherein the second surface is flush with a surface on one side of the external connection device facing away from the carrier.

10. The semiconductor packaging method of claim 3, wherein the interconnection device includes a first surface and a second surface that are opposite to each other, the first surface includes an adhesive layer, and the second surface includes connection pads; and wherein attaching the interconnection device to the carrier includes:
attaching the first surface of the interconnection device to the carrier, wherein the second surface is flush with a surface on one side of the external connection device facing away from the carrier.

11. The semiconductor packaging method of claim 4, wherein the interconnection device includes a first surface and a second surface that are opposite to each other, the first surface includes an adhesive layer, and the second surface includes connection pads; and wherein attaching the interconnection device to the carrier includes:
attaching the first surface of the interconnection device to the carrier, wherein the second surface is flush with a surface on one side of the external connection device facing away from the carrier.

12. The semiconductor packaging method of claim 5, wherein the interconnection device includes a first surface and a second surface that are opposite to each other, the first surface includes an adhesive layer, and the second surface includes connection pads; and wherein attaching the interconnection device to the carrier includes:
attaching the first surface of the interconnection device to the carrier, wherein the second surface is flush with a surface on one side of the external connection device facing away from the carrier.

13. The semiconductor packaging method according to claim 2, wherein the active surface of the first semiconductor device includes third bumps; and wherein electrically connecting the active surface of the first semiconductor device to the external connection device and the interconnection device includes:
electrically connecting the first semiconductor device to the external connection device through some of the third bumps and to the interconnection device through the rest of the third bumps.

14. The semiconductor packaging method according to claim 3, wherein the active surface of the first semiconductor device includes third bumps; and wherein electrically connecting the active surface of the first semiconductor device to the external connection device and the interconnection device includes:
electrically connecting some of the third bumps to the external connection device and the rest of the third bumps to the interconnection device.

15. The semiconductor packaging method according to claim 4, wherein the active surface of the first semiconductor device includes third bumps; and wherein electrically connecting the active surface of the first semiconductor device to the external connection device and the interconnection device includes:
electrically connecting some of the third bumps to the external connection device and the rest of the third bumps to the interconnection device.

16. The semiconductor packaging method according to claim 5, wherein the active surface of the first semiconductor device includes third bumps; and wherein electrically connecting the active surface of the first semiconductor device to the external connection device and the interconnection device includes:
electrically connecting some of the third bumps to the external connection device and the rest of the third bumps to the interconnection device.

17. The semiconductor packaging method according to claim 2, further comprising:
removing the carrier to expose the external connection device and the interconnection device;
forming a second redistribution layer on one side of the external connection device facing away from the first semiconductor device; and
forming fourth bumps on one side of the second redistribution layer facing away from the external connection device.

18. The semiconductor packaging method according to claim 3, further comprising:
removing the carrier to expose the external connection device and the interconnection device;
forming a second redistribution layer on one side of the external connection device facing away from the first semiconductor device; and
forming fourth bumps on one side of the second redistribution layer facing away from the external connection device.

19. A semiconductor component, assembled by the semiconductor packaging method according to claim 1.

20. An electronic device, comprising the semiconductor component according to claim 19.
